(19) United States
(12) Patent Application Publication
(10) Pub. No.: US 2025/0311398 A1
(43) Pub. Date: Oct. 2, 2025

(54) HIGH VOLTAGE SEMICONDUCTOR DEVICE INCLUDING BOOTSTRAP SCHOTTKY DIODE

(71) Applicant: SK keyfoundry Inc., Cheongju-si (KR)

(72) Inventor: Youngbae KIM, Sejong-si (KR)

(73) Assignee: SK keyfoundry Inc., Cheongju-si (KR)

(21) Appl. No.: 18/927,272

(22) Filed: Oct. 25, 2024

(30) Foreign Application Priority Data
Mar. 29, 2024 (KR) 10-2024-0042913

(51) Int. Cl. H01L 27/06; H01L 29/06; H01L 29/40; H01L 29/49; H01L 29/808; H01L 29/872

(52) U.S. Cl. CPC H10D 84/811; H10D 8/60; H10D 30/83; H10D 62/107; H10D 62/111; H10D 64/112; H10D 64/668

(57) ABSTRACT

A semiconductor device includes a junction isolation region, a Schottky diode including an n-type buried layer (NBL), an anode electrode, and a cathode electrode formed on the NBL, and a guard ring surrounding the Schottky diode. A source electrode of the junction isolation region is electrically connected to the cathode electrode of the Schottky diode.

### CROSS-REFERENCE TO RELATED APPLICATIONS

This application claims the benefit under 35 U.S.C. § 119(a) of Korea Patent Application No. 10-2024-0042913 filed on Mar. 29, 2024 in the Korean Intellectual Property Office, the entire disclosure of which is incorporated herein by this reference for all purposes.

### BACKGROUND

### 1. Field

The following description relates to a high voltage (HV) semiconductor device including a bootstrap Schottky diode.

### 2. Description of the Related Art

To turn on a power semiconductor, such as an n-type metal oxide semiconductor field effect transistor (MOSFET) or insulated gate bipolar transistor (IGBT), a high positive voltage must be applied to the gate. A bootstrap circuit can be used to apply a high positive voltage to a power semiconductor.

A bootstrap circuit comprises a bootstrap diode and a bootstrap capacitor. In a bootstrap circuit, a capacitor is charged with voltage when the diode is turned on, and a power supply voltage and the voltage charged on the capacitor are applied to ensure that enough voltage is applied to the gate of the power semiconductor.

In one aspect, a PN diode or a Schottky diode can be used as a bootstrap diode. When a Schottky diode is used, a large amount of leakage current may be generated in a direction of the substrate of the bootstrap diode. In addition, it is necessary to protect the bootstrap diode from high voltage (HV) in order for the bootstrap diode to operate reliably.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Various examples of the present disclosure are designed to overcome the problems described above. It is an object of the present disclosure to provide a semiconductor device capable of reducing leakage current in the substrate direction of a bootstrap Schottky diode and protecting the bootstrap Schottky diode from high voltage.

The technical problems that the present disclosure seeks to overcome are not limited to the technical problems described above. Other technical problems not mentioned will be apparent to those skilled in the art from the examples of the present disclosure.

In one general aspect, a semiconductor device includes: a junction isolation region including a deep n-type well region (DNW) formed on a substrate, a highly doped n-type (N+) source region and an N+ drain region formed in the DNW, a P-type body region (PBODY) formed in the DNW and disposed between the N+ source region and the N+ drain region, and a source electrode and a drain electrode respectively connected to the N+ source region and the N+ drain region; a Schottky diode including an n-type buried layer (NBL) formed on the substrate, and an anode electrode and a cathode electrode formed on the NBL; and a guard ring surrounding the Schottky diode, including the NBL extended from the Schottky diode, a first deep p-type well region (DPW) and an n-type well region (NW) formed on the NBL, a p-type buried layer (PBL) formed in contact with the NBL, and a second DPW formed on the PBL. The source electrode of the junction isolation region is electrically connected to the cathode electrode of the Schottky diode.

The Schottky diode may further include: the DNW extended from the junction isolation region, two deep p-type well regions formed in the DNW, an anode Schottky barrier layer formed in contact with the DNW and disposed between the two deep p-type well regions, an n-type cathode region formed adjacent to one of the two deep p-type well regions, and a cathode silicide layer formed on the n-type cathode region. The two deep p-type well regions may be in direct contact with the anode Schottky barrier layer.

The junction isolation region may further include: a gate electrode disposed on the PBODY and electrically connected to a gate terminal, a highly doped p-type (P+) body contact region formed in the PBODY, a first p-type buried top layer (P-TOP) formed in the DNW and in contact with the PBODY, a field oxide layer (FOX) formed on the P-TOP, a first field plate electrically connected to the drain electrode, and a second field plate electrically connected to the gate electrode.

An n-channel junction field-effect transistor (JFET) is formed from the junction isolation region and the guard ring, and the n-channel JFET includes the N+ source region, the N+ drain region, a gate region comprising the PBODY and the first DPW, and an n-type channel region comprising the DNW.

The semiconductor device may further include a plurality of floating field plates formed on the FOX in the junction isolation region. No electrodes may be connected to the plurality of floating field plates.

The semiconductor device may further include a second P-TOP disposed on the first P-TOP formed in the DNW and spaced apart from the first P-TOP.

In another general aspect, a semiconductor device includes: a junction isolation region including a deep n-type well region (DNW) formed on a substrate, a highly doped n-type (N+) source region and an N+ drain region formed in the DNW, a P-type body region (PBODY) formed in the DNW and disposed between the N+ source region and the N+ drain region, and a source electrode and a drain electrode respectively connected to the N+ source region and the N+ drain region; a Schottky diode including a first n-type buried layer (NBL) formed on the substrate, and an anode electrode and a cathode electrode formed on the first NBL; and a guard ring surrounding the Schottky diode, including a first p-type buried layer (PBL) formed in contact with the first NBL of the Schottky diode, a first deep p-type well region (DPW) formed on the first PBL, a second NBL in contact with the first PBL, a first n-type well region (NW) formed on the second NBL, a second PBL in contact with the second NBL, and a second DPW formed on the second PBL. The source electrode of the junction isolation region is electrically connected to the cathode electrode of the Schottky diode.

The Schottky diode may further include the DNW extended from the junction isolation region, two deep p-type well regions formed in the DNW, an anode Schottky barrier layer formed in contact with the DNW and disposed between the two deep p-type well regions, an n-type cathode region formed adjacent to one of the two deep p-type well regions, and a cathode silicide layer formed on the n-type cathode region. The two deep p-type well regions may be in direct contact with the anode Schottky barrier layer.

The junction isolation region may further include a gate electrode disposed on the PBODY and electrically connected to a gate terminal, a highly doped p-type (P+) body contact region formed in the PBODY, a first p-type buried top layer (P-TOP) formed in the DNW and in contact with the PBODY, a field oxide layer (FOX) formed on the P-TOP, a first field plate electrically connected to the drain electrode, and a second field plate electrically connected to the gate electrode.

An n-channel junction field-effect transistor (JFET) may be formed from the junction isolation region and the guard ring, and the n-channel JFET includes the N+ source region, the N+ drain region, a gate region including the PBODY and the first DPW, and an n-type channel region including the DNW.

The semiconductor device may further include a plurality of floating field plates formed on the FOX in the junction isolation region. No electrodes may be connected to the plurality of floating field plates.

The semiconductor device may further include a second P-TOP disposed on the first P-TOP formed in the DNW and spaced apart from the first P-TOP.

Effects which may be obtained by the present disclosure are not limited to the aforementioned effects, and other technical effects not described above may be evidently understood by a person having ordinary skill in the art to which the present disclosure pertains from the following description.

### BRIEF DESCRIPTION OF THE DRAWINGS

FIG. 1 illustrates a HV semiconductor device including a bootstrap Schottky diode according to an example of the present disclosure.

FIG. 2 illustrates a cross-sectional view of the HV semiconductor device including the bootstrap Schottky diode according to the example of the present disclosure, and illustrates a cross-sectional view taken along line A-A′ of FIG. 1.

FIG. 3 illustrates a cross-sectional view of a HV semiconductor device including a bootstrap Schottky diode according to another example of the present disclosure and illustrates a cross-sectional view taken along line A-A′ of FIG. 1.

FIG. 4 illustrates a cross-sectional view of a HV semiconductor device including a bootstrap Schottky diode according to another example of the present disclosure and illustrates a cross-sectional view taken along line A-A′ of FIG. 1.

FIG. 5 illustrates a cross-sectional view of a HV semiconductor device including a bootstrap Schottky diode according to another example of the present disclosure and illustrates a cross-sectional view taken along line A-A′ of FIG. 1.

FIG. 6 illustrates a cross-sectional view of a HV semiconductor device including a bootstrap Schottky diode according to another example of the present disclosure and illustrates a cross-sectional view taken along line A-A′ of FIG. 1.

FIG. 7 illustrates a block diagram for describing the operation of a HV semiconductor device according to the example of the present disclosure.

Other features and aspects will be apparent from the following detailed description, the drawings, and the claims.

### DETAILED DESCRIPTION

The features, advantages and method for accomplishment of the present disclosure will be more apparent from referring to the following detailed examples described as well as the accompanying drawings. However, the present disclosure is not limited to the example to be disclosed below and is implemented in different and various forms. The examples bring about the complete disclosure of the present disclosure and are only provided to make those skilled in the art fully understand the scope of the present disclosure. The present disclosure is just defined by the scope of the appended claims. The same reference numerals throughout the disclosure correspond to the same elements.

What one component is referred to as being “connected to” or “coupled to” another component includes both a case where one component is directly connected or coupled to another component and a case where a further another component is interposed between them. Meanwhile, what one component is referred to as being “directly connected to” or “directly coupled to” another component indicates that a further another component is not interposed between them. The term “and/or” includes each of the mentioned items and one or more all of combinations thereof.

Terms used in the present specification are provided for description of only specific examples of the present disclosure, and not intended to be limiting. In the present specification, an expression of a singular form includes the expression of plural form thereof if not specifically stated. The terms “comprises” and/or “comprising” used in the specification is intended to specify characteristics, numbers, steps, operations, components, parts or any combination thereof which are mentioned in the specification, and intended not to exclude the existence or addition of at least one another characteristics, numbers, steps, operations, components, parts or any combination thereof.

While terms such as the first and the second, etc., can be used to describe various components, the components are not limited by the terms mentioned above. The terms are used only for distinguishing between one component and other components.

Therefore, the first component to be described below may be the second component within the spirit of the present disclosure. Unless differently defined, all terms used herein including technical and scientific terms have the same meaning as commonly understood by one of ordinary skill in the art to which the present disclosure belongs. Also, commonly used terms defined in the dictionary should not be ideally or excessively construed as long as the terms are not clearly and specifically defined in the present application.

A term “module” or “unit” used in the examples of the present disclosure means a hardware component such as software or a field programmable gate array (FPGA) or an application specific integrated circuit (ASIC), and the “unit” or “module” performs certain roles. However, “unit” or “module” is not limited to software or hardware. The “unit” or “module” may be configured to be positioned in an addressable storage medium or may be configured to regenerate one or more processors. Thus, as an example, the “unit” or “module” may include components such as software components, object-oriented software components, class components, and task components, processes, functions, properties, procedures, subroutines, segments of program code, drivers, firmware, microcode, circuitry, data, databases, data structures, tables, arrays, and variables. Functions provided within components and “unit” or “modules” may be separated into smaller numbers of components and “units” or “modules” or integrated into additional components and “unit” or “modules”.

Methods or algorithm steps described relative to some examples of the present disclosure may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the record medium may be resident within an application specific integrated circuit (ASIC). The ASIC may be resident within a user's terminal.

Hereafter, an example of the present disclosure will be described in detail such that those skilled in the art to which the present disclosure belongs will embody the technical idea of the present disclosure with reference to the accompanying drawings. However, the present disclosure may be embodied in various forms and is not limited to the example described in the present specification.

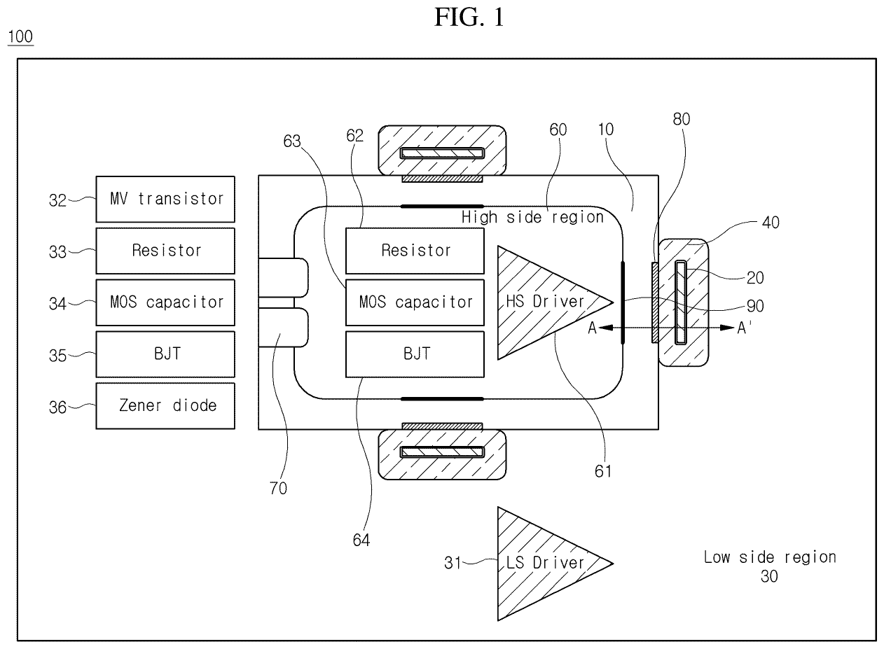

FIG. 1 illustrates a plan view of a HV semiconductor device including a bootstrap Schottky diode according to an example of the present disclosure.

Referring to FIG. 1, a HV semiconductor device 100 may comprise a junction isolation region 10, a bootstrap Schottky diode 20, a low side region 30, a guard ring 40 and a high side (HS) region 60.

In the HV semiconductor device 100, a sufficient voltage may be charged to a bootstrap capacitor (not shown) by a forward current of the bootstrap Schottky diode 20. Therefore, a sufficient voltage is applied to a gate of a high side MOSFET (not shown) to be operated, so that the high side MOSFET can operate smoothly. A plurality of the bootstrap Schottky diodes 20 surrounded by the guard ring 40 may be disposed, or only one bootstrap Schottky diode 20 may be disposed when a sufficient forward current is generated. However, the bootstrap Schottky diode 20 is not limited to this.

In the low side (LS) region 30, a low side (LS) gate driver 31, a medium voltage (MV) transistor 32, a resistor 33, a metal-oxide-semiconductor (MOS) capacitor 34, a bipolar junction transistor (BJT) 35, and a Zener diode 36 may be formed. Here, the low side gate driver 31 is a gate driver for operating a low side MOSFET (not shown). Also, a level shifter 70 formed to overlap the junction isolation region 10 and extended to the high side region 60 may be disposed.

The guard ring 40 may be formed to completely surround the bootstrap Schottky diode 20 in order to isolate the bootstrap Schottky diode 20 from the low side region 30.

In the high side (HS) region 60, a high side (HS) gate driver 61, a resistor 62, a metal-oxide-semiconductor (MOS) capacitor 63, and a bipolar junction transistor (BJT) 64 may be formed. Here, the high side gate driver 61 is a gate driver for operating a high side MOSFET (not shown).

A source region 80 and a drain region 90 may be formed in the junction isolation region 10. The source region 80 may be formed between the junction isolation region 10 and the guard ring 40. The source region 80 may be electrically connected to a cathode electrode (not shown) in the Schottky diode 20 through a source/cathode electrode. The forward current from the Schottky diode 20 may be transmitted to the junction isolation region 10.

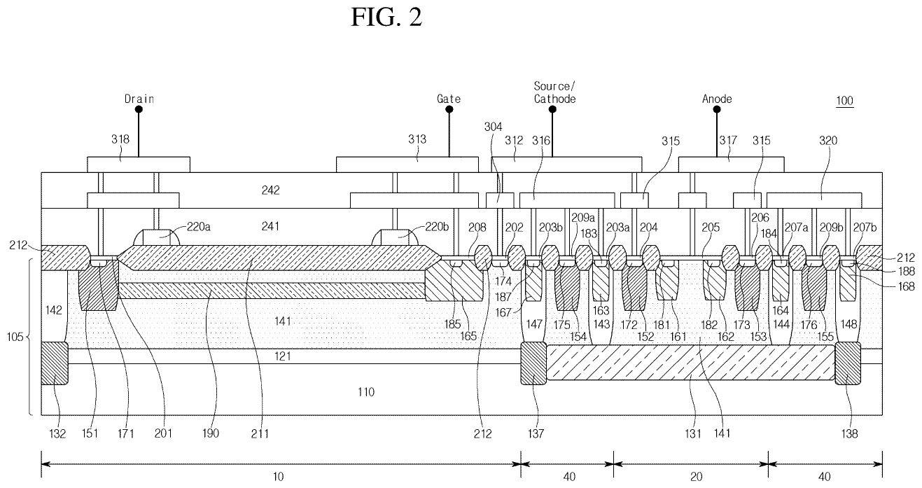

FIG. 2 illustrates a cross-sectional view of the HV semiconductor device including the bootstrap Schottky diode according to the example of the present disclosure and illustrates a cross-sectional view taken along line A-A′ of FIG. 1.

Referring to FIG. 2, the HV semiconductor device 100 may include the junction isolation region 10, the Schottky diode 20 and the guard ring 40 surrounding the Schottky diode 20.

The junction isolation region 10 may include a semiconductor substrate 110. The semiconductor substrate 110 may include a low concentration first conductivity type (hereinafter, referred to as p-type) semiconductor substrate or a low concentration second conductivity type (hereinafter, referred to as n-type) semiconductor substrate 110. In the example of the present disclosure, the p-type semiconductor substrate (P-sub) 110 will be described as an example.

The n-type or p-type epitaxial layer 121 may be formed on the P-sub 110 in the junction isolation region 10. The n-type or p-type epitaxial layer 121 may be grown after the n-type buried layer (NBL) 131 may be formed. Since the n-type or p-type epitaxial layer 121 may be formed at a high temperature, the dopants in the NBL 131 are diffused into the n-type or p-type epitaxial layer 121 or the P-sub 110, so that the width of the NBL 131 may increase up and down. That is, the dopants of the NBL 131 are diffused in both directions, and the thickness resulting from the diffusion of the dopants of the NBL 131 may become greater than the thickness formed by initial ion implantation.

An n-type semiconductor region 141 may be formed on the n-type or p-type epitaxial layer 121 in the junction isolation region 10. The n-type semiconductor region 141 may provide an n-type channel in on-state. The n-type semiconductor region 141 may also be referred to as a deep n-type well (DNW) 141. Hereinafter, the DNW 141 may refer to the n-type semiconductor region 141. The DNW 141 may be formed by ion implantation of an n-type dopant and a high-temperature drive-in annealing process. The DNW 141 may be formed at a low concentration in order to endure a high voltage, and may have a concentration that is 1 to 2 order less than a doping concentration of the NBL 131. The DNW 141 in the junction isolation region 10 may be tens of times greater than the DNW 141 in the Schottky diode 20. Therefore, the left and right length of the DNW 141 may be designed to withstand a much higher voltage, for example, 600 V, and is not limited thereto. So the semiconductor substrate 105 may comprise the P-sub 110, NBL 131, n-type or p-type epitaxial layer 121 and the DNW 141.

In the junction isolation region 10, an n-type well (NW) 151, a highly doped n-type (N+) drain region 171 and a highly doped n-type (N+) source region 174 may be formed in the DNW 141. Silicide layers 201 and 202 may be respectively formed on the N+ drain region 171 and the N+ source region 174. A source electrode 304 and a drain electrode 318 may be electrically connected to the N+ source region 174 and N+ drain region 171, respectively. Here, the source electrode 304 may be electrically connected to the cathode electrode 315 in the Schottky diode 20 through a source/cathode electrode 312.

In the junction isolation region 10, a p-type body region (PBODY) 165 may be formed in the DNW 141. A p-type highly doped (P+) body contact region 185 may be formed in the PBODY 165. A p-type buried top layer (P-TOP) 190 may be formed in the DNW 141, which may be helpful for reducing a surface electric field (RESURF). The P-TOP 190 may be electrically connected to the PBODY 165.

A first field oxide layer (FOX) 211 and a second FOX 212 may be formed on the P-TOP 190. The first and second FOXs 211 and 212 may be formed through a shallow trench isolation (STI) process or a local oxidation of silicon (LOCOS) process for device isolation. Here, the P-TOP 190 and the first FOX 211 may be formed to be spaced apart from each other at a predetermined distance. However, in another example, the P-TOP 190 and the first FOX 211 may be formed in contact with each other. The second FOX may be formed between the N+ source region 174 and P+ body contact region 185. Further, a pre-metal insulating layer 241 and an inter-metal insulating layer 242 may be formed on the first field oxide layer (FOX) 211 and the second FOX 212.

An n-channel junction field-effect transistor (n-channel JFET) may be formed from the junction isolation region 10 and the guard ring 40. The n-channel JFET may comprise the N+ source region 174, the N+ drain region 171, a gate region comprising the PBODY 165 and the deep p-type well (DPW) 147, and a channel region comprising the DNW 141. The n-channel JFET current flows from the N+ drain region 171 to N+ source region 174. Electric charge flows through the n-type semiconducting channel of the DNW 141 between the source electrode 304 and the drain electrode 318. As drain voltage increases, the gate depletion region expands towards the drain. This increases the length of the narrow channel, which increases its resistance. The n-type channel is pinched, and the electric current is completely switched off.

A first field plate 220a may be formed on one side of the first FOX 211 in the junction isolation region 10. The first field plate 220a may be connected to the drain electrode 318. On the other hand, a second field plate 220b may be formed on the other side of the first FOX 211, which is spaced apart from the first field plate 220a. The first and second field plates 220a and 220b may comprise a Poly-Si. The second field plate 220b may be connected to the gate terminal 313 which may receive a ground voltage.

The first and second field plates 220a and 220b may all serve to reduce a peak electric field. That is, the regions serve to help a surface electric field concentrated on the surface of the substrate 105. It is advantageous to drive the HV semiconductor device 100 according to the example of the present disclosure at a high voltage.

Further, a p-type guard ring comprising PBL 132 and DPW 142 may be formed adjacent to the NW 151 and N+ drain region 171 to electrically isolate the junction isolation region 10 from a peripheral circuit area (not shown).

The drain electrode 318 of the junction isolation region 10 may be connected to a second power terminal Vb (not shown). Also, a bootstrap capacitor CB (not shown) connected to the second power terminal Vb may be placed. Therefore, the junction isolation region 10 may be connected to the second power terminal Vb and the bootstrap capacitor CB through the drain electrode 318. Also, the junction isolation region 10 may receive a forward bias voltage, such as, a driving voltage (Vcc) from the cathode electrode 315 of the Schottky diode 20.

The Schottky diode 20 may comprise an n-type buried layer (NBL) 131 formed on the P-sub 110. The NBL 131 may be formed by ion implantation of a high concentration n-type dopant into the P-sub 110 before the n-type or p-type epitaxial layer 121 is formed. Alternatively, the NBL 131 may be formed by ion implantation of a dopant into the substrate 110 using high ion-implantation energy. When the Schottky diode 20 is operating, the NBL 131 may be formed to reduce the leakage current flowing from the Schottky diode 20 to the P-sub 110. The leakage current may be significantly reduced by the NBL 131 due to its high doping concentration. The NBL 131 may further extend into the guard ring 40 to reduce leakage current to the substrate 110 starting from the Schottky diode 20.

The DNW 141 may be formed over the NBL 131 in the Schottky diode 20. Further, N-type well regions (NWs) 152 and 153 and N+ regions 172 and 173 are formed in the NWs 152 and 153, respectively, to form a cathode region in the Schottky diode 20. Silicide layers 204 and 206 are respectively formed in contact with the N+ regions 172 and 173 in the cathode region.

A first deep p-type well (DPW) 161 and a second DPW 162 may be formed in the DNW 141 in the Schottky diode 20. A first P+ region 181 and a second P+ region 182 may be formed in the first DPW 161 and the second DPW 162, respectively. The first and second DPWs 161 and 162 and the first and second P+ regions 181 and 182 may improve a breakdown voltage of the Schottky diode 20. The DPWs 161 and 162 and P+ regions 181 and 182 may surround the bottom corner of the FOX 212, so the electric field around the bottom corner may be reduced, improving the breakdown voltage.

An anode Schottky barrier layer 205 may be formed in direct contact with the DNW 141. The anode Schottky barrier layer 205 may include a metal silicide layer such as CoSi2, TiSi2, PtSi2, or NiSi. The first DPW 161, the second DPW 162, the first P+ region 181 and the second P+ region 182 may also directly contact the anode Schottky barrier layer 205. In other words, the DPWs 161 and 162, and P+ regions 181 and 182 may be formed in contact with the metal silicide layer.

Anode electrode 317 and cathode electrode 315 may be formed in the Schottky diode 20. The anode electrode 317 may be coupled to the anode Schottky barrier layer 205. The cathode electrode 315 may be electrically coupled to the silicide layers 204 and 206 in the cathode region.

The anode electrode 317 may be connected to a driving power circuit and may receive a driving voltage Vcc. After the forward current passes through the anode electrode 317, the forward current may pass through the anode Schottky barrier layer 205 and the DNW 141, and then may pass through the cathode region comprising NW 152 and 153, N+ regions 172 and 173, the silicide layers 204 and 206, and the cathode electrode 315. Also, the cathode electrode 315 may be electrically connected to the source electrode 304 through a source/cathode electrode 312. Thus, the forward current may flow into the junction isolation region 10, and it may flow from the N+ source region 174 to the N+ drain region 171 through the DNW 141 to charge the bootstrap capacitor CB.

A driving power circuit may be disposed adjacent to the Schottky diode 20 such that the Schottky diode 20 receives a driving voltage Vcc (not shown). The Schottky diode 20 may be connected to the driving power circuit through the anode electrode 317. The driving power circuit may supply the driving voltage Vcc to the anode electrode 317. The driving voltage Vcc may be a low voltage of about 30 V, but is not limited thereto. The Schottky diode 20 may transmit a forward bias current generated by the driving voltage Vcc supplied to the anode electrode 317 and to the junction isolation region 10 through the cathode electrode 315.

The guard ring 40 may comprise the NBL 131, the first p-type buried layer (PBL) 137 and the second PBL 138 formed on the P-sub 110, wherein the first PBL 137 and second PBL 138 are electrically connected together. A first DPW 143 and a second DPW 144 may be formed on the NBL 131. A third DPW 147 and a fourth DPW 148 may be respectively formed on the first PBL 137 and the second PBL 138.

In the guard ring 40, a first PW 163, a second PW 164, a third PW 167 and a fourth PW 168 respectively formed in the first DPW 143, the second DPW 144, the third DPW 147 and the fourth DPW 148. A first NW 154 and a second NW 155 may be formed in the DNW 141. A first P+ 183, a second P+ 184, a third P+ 187 and a fourth P+ 188 may be respectively formed in the first PW 163, the second PW 164, the third PW 167 and the fourth PW 168. A first N+ 175 and a second N+176 may be respectively formed in the first NW 154 and the second NW 155.

Electrodes 316 and 320 may be further formed in the guard ring 40 to provide a ground voltage. Therefore, the ground voltage may be applied to the P+ regions 183, 184, 187 and 188, the N+ regions 175 and 176 disposed in the guard ring 40.

By using the guard ring 40, leakage current that may flow in the direction of the P-sub 110 of the bootstrap Schottky diode 20 can be reduced. When the bootstrap Schottky diode 20 is turned on, a forward current may be generated in the bootstrap Schottky diode 20.

Also, at the same time, significant leakage current may be generated from the NW 152 of the cathode region toward the first DPW 143 disposed in the guard ring 40. The NBL 131 of the Schottky diode 20 extends to form below the first DPW 143 of the guard ring 40, so that it can sufficiently block the leakage current flowing from the first DPW 143 to the P-sub 110. Therefore, the NBL 131 is required under the first DPW 143.

In the same manner, the NBL 131 disposed below the first NW 154 in the guard ring 40 may reduce the leakage current flowing into the P-sub 110 from the first NW 154. For the reasons mentioned above, the NBL 131 may extend from the bootstrap Schottky diode 20 to the guard ring 40. The NBL 131 may have a horizontal length greater than a horizontal length of the bootstrap Schottky diode 20. The length of the NBL 131 may be greater than each length of the PBLs 137 and 138.

Herein, a pinch-off region may be formed between the third DPW 147 and the PBODY 165 in an off-state of the HV semiconductor device 100 to protect the Schottky diode 20. In a reverse bias state, each depletion region of the third DPW 147 and the PBODY 165 is extended into each other, and pinch-off may occur. For example, when a high voltage flows from the drain electrode 318, the high voltage may be prevented from flowing into the bootstrap Schottky diode 20 by the pinch-off region. As a result, the bootstrap Schottky diode 20 can be protected. The guard ring 40 can protect the bootstrap Schottky diode 20 from the high voltage originating from the drain electrode 318.

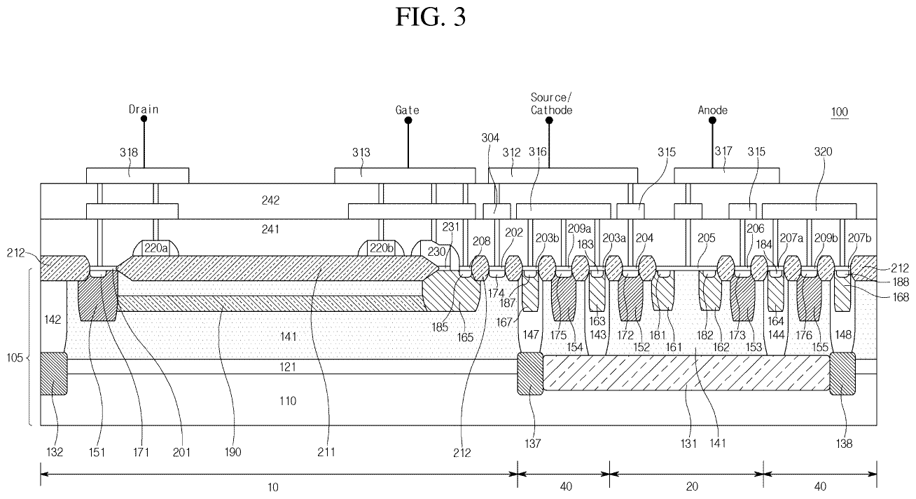

FIG. 3 illustrates a cross-sectional view of a HV semiconductor device including a bootstrap Schottky diode according to another example of the present disclosure.

FIG. 3 is similar to FIG. 2 except a gate electrode 230 formed on the PBODY 165 in the junction isolation region 10.

A gate insulating layer 231 may be formed on the PBODY 165, and the gate electrode 230 may be formed on the gate insulating layer 231 in the junction isolation region 10. The gate electrode 230 may be connected to the gate terminal 313 which is coupled to the ground voltage. The gate electrode 230 may help reduce the high peak electric field between the drain electrode 318 and the source electrode 304. Further, the second field plate 220b may be connected to the gate electrode 230 and finally to the gate terminal 313 which may receive a ground voltage. A silicide layer 208 may be formed on the P+ body contact region 185 and the silicide layer 208 may be also connected to the gate terminal 313.

An n-channel junction field-effect transistor (JFET) may be formed in the junction isolation region 10. The n-channel JFET may comprise the N+ source region 174, the N+ drain region 171, a gate region comprising the PBODY 165 and the DPW 147, and a channel region comprising the DNW 141. The n-channel JFET current flows from the N+ drain region 171 to the N+ source region 174. Electric charge flows through n-type semiconducting channel of the DNW 141 between the source electrode 304 and the drain electrode 318. As drain voltage increases, the gate depletion region expands toward the drain. This increases the length of the narrow channel, which increases its resistance. The n-type channel is pinched and the electric current is completely switched off. JFETs are depletion-mode devices because they rely on the principle of a depletion region. The depletion region has to be closed to enable current to flow.

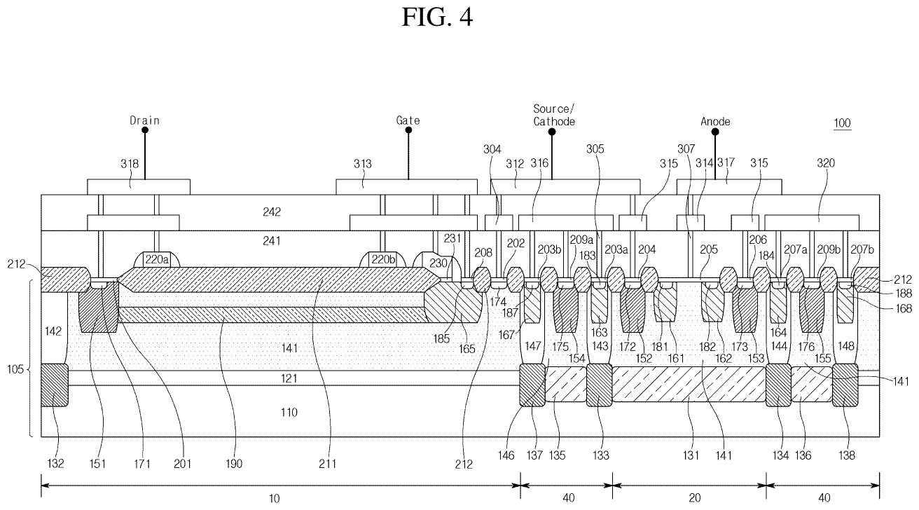

FIG. 4 illustrates a cross-sectional view of a HV semiconductor device including a bootstrap Schottky diode according to another example of the present disclosure and illustrates a cross-sectional view taken along line A-A′ of FIG. 1.

Referring to FIG. 4, the guard ring 40 of the HV semiconductor device 100 according to the example may include a PNP guard ring structure. Since the remaining components are similar to those in FIG. 3, the PNP guard ring structure will be mainly described. The PNP guard ring structure may include a first p-type guard ring, an n-type guard ring and a second p-type guard ring.

The first p-type guard ring may comprise PBLs 133 and 134, DPWs 143 and 144, PWs 163 and 164 and P+ regions 183 and 184.

The n-type guard ring may comprise NBLs 135 and 136, NWs 154 and 155 and N+ regions 175 and 176.

The second p-type guard ring may comprise PBLs 137 and 138, DPWs 147 and 148, PWs 167 and 168 and P+regions 187 and 188.

All the first p-type guard ring, the n-type guard ring and the second p-type guard ring may be connected to the ground electrodes 316 and 320 and may receive a ground voltage. The guard ring 40 comprising the first p-type guard ring, the n-type guard ring and the second p-type guard ring may surround the Schottky diode 20.

The first p-type guard rings 133, 143, 163, 183, 134, 144, 164, and 184, the n-type guard rings 135, 154, 175, 136, 155, and 176, and the second p-type guard rings 137, 147, 167, 187, 138, 148, 168, and 188

The use of the PNP guard ring structure in the guard ring 40 can reduce the leakage current of the bootstrap Schottky diode 20. When the bootstrap Schottky diode 20 is turned on, a forward current flowing from the cathode electrode to the source electrode may be generated in the bootstrap Schottky diode 20. Also, leakage current may occur at the same time. However, leakage current can be sufficiently blocked by the PNP guard ring structure.

The PNP guard ring structure shown in FIG. 4 may be formed in the HV semiconductor device 100 shown in FIGS. 2 to 6, and detailed description thereof will be omitted below.

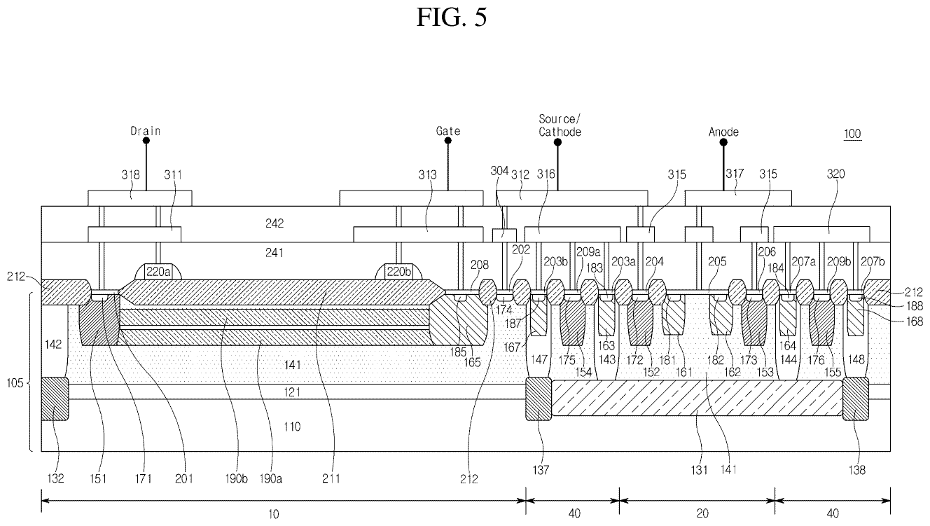

FIG. 5 illustrates a cross-sectional view of a HV semiconductor device including a bootstrap Schottky diode according to another example of the present disclosure.

Referring to FIG. 5 through a comparison with FIG. 2, in the HV semiconductor device 100 according to another example, a plurality of P-TOPs 190a and 190b may be formed to be spaced apart from each other below the FOX 211. All remaining components are the same. When a high reverse bias voltage of about 600 V is generated, the arrangement of the plurality of P-TOPs 190a and 190b may help to provide a wide depletion region in the DNW 141 between the drain electrode 318 and the source electrode 304.

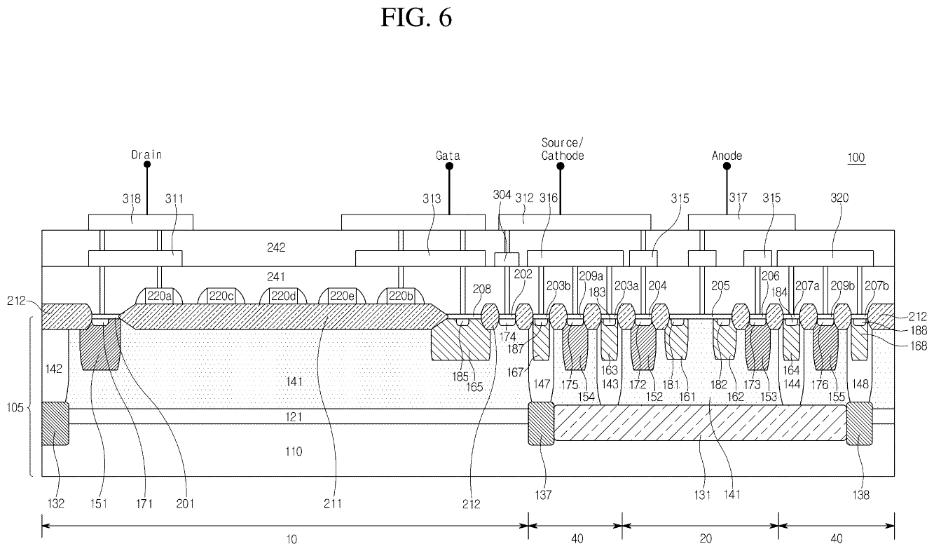

FIG. 6 illustrates a cross-sectional view of a HV semiconductor device including a bootstrap Schottky diode according to another example of the present disclosure.

Referring to FIG. 6 through a comparison with FIG. 2, the HV semiconductor device 100 according to the example may include a plurality of field plates 220c, 220d and 220e as well as 220a and 220b spaced apart from each other on the FOX 211. The plurality of field plates 220a to 220e may provide a uniform electric field distribution in the DNW 141 below the FOX 211. No electrodes are connected to the plurality of field plates 220c, 220d and 220e, which are floating field plates. The plurality of floating field plates 220c, 220d and 220e may serve as a reduced surface field (RESURF) for obtaining a target breakdown voltage and a specific on-resistance (RSP) that is a resistance when current flows in a semiconductor operating state.

Referring to FIG. 6, when a high voltage of approximately 600 V is applied to the drain electrode 318, a high peak electric field may be generated on a top surface of the substrate 110. The plurality of field plates 220a to 220e may help reduce high peak electric field. A surface electric field concentrated on the top surface of the substrate 105 may spread uniformly in the DNW 141.

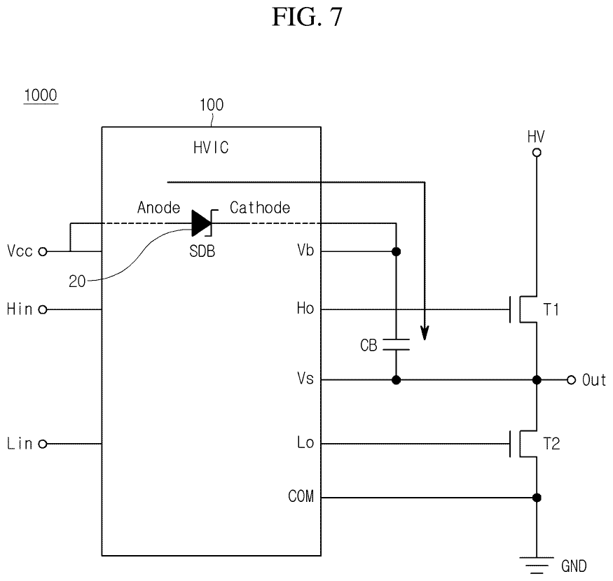

FIG. 7 illustrates a block diagram for describing the operation of a HV semiconductor device according to the example of the present disclosure.

Referring to FIG. 7, a high voltage integrated circuit (HVIC) 1000 may include a HV semiconductor device 100, a bootstrap capacitor CB, and first and second power transistors T1 and T2.

The first power transistor T1 is provided between a high voltage HV and an output terminal (Out), so that the drain may be connected to the high voltage HV and the source may be connected to the output terminal (Out). The gate of the first power transistor T1 may be connected to a high side (HS) driving output terminal (Ho) of the HV semiconductor device 100, and the first power transistor T1 may be turned on/off by the voltage output from the HS driving output terminal (Ho). When the first power transistor T1 is turned on, the high voltage HV can be output to the output terminal (Out).

The second power transistor T2 is provided between a ground GND and the output terminal (Out), so that the drain may be connected to the output terminal (Out) and the source may be connected to the ground GND. The gate of the second power transistor T2 may be connected to a low side (LS) driving output terminal (Lo) of the HV semiconductor device 100, and the second power transistor T2 may be turned on/off by the voltage output from the LS driving output terminal (Lo). When the second power transistor T2 is turned on, the ground GND can be output to the output terminal (Out).

The source of the first power transistor T1 and the drain of the second power transistor T2 may be connected to the output terminal (Out). Also, the output terminal (Out) may be connected to a first power terminal Vs of the HV semiconductor device 100. The output terminal (Out) may be connected to a load (Load).

The HV semiconductor device 100 may output a high side control signal that controls the operation of the first power transistor T1 through the HS driving output terminal (Ho) in response to a logic signal input through a high voltage input terminal (Hin).

The HV semiconductor device 100 may output a low side control signal that controls the operation of the second power transistor T2 through the LS driving output terminal (Lo) in response to a logic signal input through a low voltage input terminal (Lin).

The first power transistor T1 and the second power transistor T2 may be controlled not to be turned on at the same time. For example, while the first power transistor T1 is controlled to be turned on, the second power transistor T2 may be controlled to be turned off. Alternatively, while the first power transistor T1 is controlled to be turned off, the second power transistor T2 may be controlled to be turned on.

The bootstrap Schottky diode SDB 20 may be placed within the HV semiconductor device 100. The bootstrap Schottky diode SDB 20 and the bootstrap capacitor CB may be connected in series. The anode of the bootstrap Schottky diode SDB 20 may be connected to a driving power supply that supplies the driving voltage Vcc, and one end of the bootstrap capacitor CB may be connected to the output terminal (Out). Also, the cathode of the bootstrap Schottky diode SDB 20 and the other end of the bootstrap capacitor CB are connected to the second power terminal Vb, so that power for the control signal output to the HS driving output terminal (Ho) can be supplied.

When the second power transistor T2 is turned on and the first power transistor T1 is turned off, the voltage applied to one end of the bootstrap capacitor CB becomes the ground GND, so that a forward voltage is applied to the bootstrap Schottky diode SDB 20 and a forward bias current flows. The forward bias current is transmitted to the bootstrap capacitor CB and charges the bootstrap capacitor CB, and the second power terminal Vb is supplied with a voltage obtained by subtracting the threshold voltage of the bootstrap capacitor CB from the driving voltage Vcc. For example, if the driving voltage Vcc is 25 V, the bootstrap capacitor CB can be charged with a voltage of about 25 V.

When the first power transistor T1 is turned on and the second power transistor T2 is turned off, the voltage applied to one end of the bootstrap capacitor CB becomes a high voltage HV, so that a reverse voltage is applied to the bootstrap Schottky diode SDB 20 and a reverse bias current is blocked by the bootstrap Schottky diode SDB 20. Here, a value obtained by adding the voltage charged in the bootstrap capacitor CB to the high voltage HV applied to the one end of the bootstrap capacitor CB is applied to the second power terminal Vb. For example, in a case where the high voltage HV is 600 V and the voltage Vcc is 25 V, if the voltage charged in the capacitor CB is about 25 V, a total voltage is 625 V may be applied to the gate of the first power transistor T1. Therefore, as the total voltage of 625 V is output to the HS driving output terminal (Ho), the voltage between the source and the gate of the first power transistor T1 is made to be higher than the threshold voltage, so that the first power transistor T1 can be stably operated.

The operation of the high voltage integrated circuit (IC) 1000 will be briefly described below.

The HV semiconductor device 100 may output a low side control signal to the LS driving output terminal (Lo) in response to a signal input via the low voltage input terminal (Lin), and may turn on the second power transistor T2. To turn on the second power transistor T2, the voltage of the low side control signal output to the LS driving output terminal (Lo) may be higher than or equal to the driving voltage Vcc.

When the second power transistor T2 is turned on, the output terminal (Out) may output the ground GND. Here, in order to prevent the high voltage HV from being applied to the output terminal (Out) simultaneously with the ground GND, the first power transistor T1 must be turned off. Since the voltage at one end of the bootstrap Schottky diode SDB 20 connected to the output terminal (Out) is the ground GND, a positive voltage is applied to the bootstrap Schottky diode SDB 20, and the driving voltage Vcc is dropped by the threshold voltage through the bootstrap Schottky diode SDB 20 and then is supplied to the bootstrap capacitor CB to charge the bootstrap capacitor CB.

Next, the HV semiconductor device 100 may output a low side control signal to turn off the operation of the second power transistor T2. Also, the HV semiconductor device 100 may output the high side control signal to the HS driving output terminal (Ho) in response to a signal input through the high voltage input terminal (Hin) and may turn on the first power transistor T1. When the first power transistor T1 is turned on, the output terminal (Out) may output the high voltage HV. At this time, the second power transistor T2 must be turned off to prevent the ground GND from being applied to the output terminal (Out) at the same time as the high voltage HV.

When the first power transistor T1 is turned on and the output terminal (Out) outputs the high voltage HV, the first power terminal Vs which is connected to the output terminal (Out) and has the same potential value may receive the high voltage HV. The second power terminal Vb may be applied with a voltage obtained by adding the voltage charged in the bootstrap capacitor CB and the high voltage HV of the output terminal (Out). The voltage applied to the second power terminal Vb may be about 600 V or more, but is not limited thereto.

A reverse voltage may be applied to the bootstrap Schottky diode SDB 20 by the high voltage applied to the second power terminal Vb. When a reverse bias current due to the reverse voltage enters a low power drive circuit elements located on the anode side of the bootstrap Schottky diode SDB 20, low power drive circuit elements (the low side (LS) gate driver 31, the medium voltage (MV) transistor 32, the resistor 33, the metal-oxide-semiconductor (MOS) capacitor 34, bipolar junction transistor (BJT) 35, the Zener diode 36, etc., shown in FIG. 1) may be destroyed.

Therefore, the bootstrap Schottky diode SDB 20 is necessary to block the reverse bias current caused by the reverse voltage. In particular, the bootstrap Schottky diode SDB 20 should have a high withstand voltage to sufficiently block the reverse bias current even when a high voltage of 600 V or more is applied by the reverse voltage.

As described in FIGS. 2 to 6, in order to protect the bootstrap Schottky diode SDB 20, the guard ring structure surrounding the bootstrap Schottky diode SDB 20 is required. The guard ring structure requires the PNP guard ring structure or one p-type doped region structure. Also, the JFET structure must be placed such that a high voltage of 600 V or more by the reverse voltage can be reduced, and several field plate structures and the p-type body region must be placed to reduce the electric field. Also, the n-type buried layer may be used to reduce the leakage current of the bootstrap Schottky diode SDB 20.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
a junction isolation region comprising:
a deep n-type well region (DNW) formed on a substrate,
a highly doped n-type (N+) source region and an N+ drain region formed in the DNW,
a P-type body region (PBODY) formed in the DNW and disposed between the N+ source region and the N+ drain region, and
a source electrode and a drain electrode respectively connected to the N+ source region and the N+ drain region;
a Schottky diode comprising:
an n-type buried layer (NBL) formed on the substrate, and
an anode electrode and a cathode electrode formed on the NBL; and
a guard ring surrounding the Schottky diode, comprising:
the NBL extended from the Schottky diode,
a first deep p-type well region (DPW) and an n-type well region (NW) formed on the NBL,
a p-type buried layer (PBL) formed in contact with the NBL, and
a second DPW formed on the PBL,
wherein the source electrode of the junction isolation region is electrically connected to the cathode electrode of the Schottky diode.

2. The semiconductor device of claim 1, wherein the Schottky diode further comprises:
the DNW extended from the junction isolation region;
two deep p-type well regions formed in the DNW;
an anode Schottky barrier layer formed in contact with the DNW and disposed between the two deep p-type well regions;
an n-type cathode region formed adjacent to one of the two deep p-type well regions; and
a cathode silicide layer formed on the n-type cathode region,
wherein the two deep p-type well regions are in direct contact with the anode Schottky barrier layer.

3. The semiconductor device of claim 1, wherein the junction isolation region further comprises:
a gate electrode disposed on the PBODY and electrically connected to a gate terminal;
a highly doped p-type (P+) body contact region formed in the PBODY;
a first p-type buried top layer (P-TOP) formed in the DNW and in contact with the PBODY;
a field oxide layer (FOX) formed on the P-TOP;
a first field plate electrically connected to the drain electrode; and
a second field plate electrically connected to the gate electrode.

4. The semiconductor device of claim 1, wherein an n-channel junction field-effect transistor (JFET) is formed from the junction isolation region and the guard ring, and
wherein the n-channel JFET comprises the N+ source region, the N+ drain region, a gate region comprising the PBODY and the first DPW, and an n-type channel region comprising the DNW.

5. The semiconductor device of claim 3, further comprising:
a plurality of floating field plates formed on the FOX in the junction isolation region,
wherein no electrodes are connected to the plurality of floating field plates.

6. The semiconductor device of claim 3, further comprising:
a second P-TOP disposed on the first P-TOP formed in the DNW and spaced apart from the first P-TOP.

7. A semiconductor device comprising:
a junction isolation region comprising:
a deep n-type well region (DNW) formed on a substrate,
a highly doped n-type (N+) source region and an N+drain region formed in the DNW,
a P-type body region (PBODY) formed in the DNW and disposed between the N+ source region and the N+ drain region, and
a source electrode and a drain electrode respectively connected to the N+ source region and the N+ drain region;
a Schottky diode comprising:
a first n-type buried layer (NBL) formed on the substrate, and
an anode electrode and a cathode electrode formed on the first NBL; and
a guard ring surrounding the Schottky diode, comprising:
a first p-type buried layer (PBL) formed in contact with the first NBL of the Schottky diode,
a first deep p-type well region (DPW) formed on the first PBL,
a second NBL in contact with the first PBL,
a first n-type well region (NW) formed on the second NBL,
a second PBL in contact with the second NBL, and
a second DPW formed on the second PBL,
wherein the source electrode of the junction isolation region is electrically connected to the cathode electrode of the Schottky diode.

8. The semiconductor device of claim 7, wherein the Schottky diode further comprises:
the DNW extended from the junction isolation region;
two deep p-type well regions formed in the DNW;
an anode Schottky barrier layer formed in contact with the DNW and disposed between the two deep p-type well regions;
an n-type cathode region formed adjacent to one of the two deep p-type well regions; and
a cathode silicide layer formed on the n-type cathode region,
wherein the two deep p-type well regions are in direct contact with the anode Schottky barrier layer.

9. The semiconductor device of claim 7, wherein the junction isolation region further comprises:
a gate electrode disposed on the PBODY and electrically connected to a gate terminal;
a highly doped p-type (P+) body contact region formed in the PBODY;
a first p-type buried top layer (P-TOP) formed in the DNW and in contact with the PBODY;
a field oxide layer (FOX) formed on the P-TOP;
a first field plate electrically connected to the drain electrode; and
a second field plate electrically connected to the gate electrode.

10. The semiconductor device of claim 7, wherein an n-channel junction field-effect transistor (JFET) is formed from the junction isolation region and the guard ring, and
wherein the n-channel JFET comprises the N+ source region, the N+ drain region, a gate region comprising the PBODY and the first DPW, and an n-type channel region comprising the DNW.

11. The semiconductor device of claim 9, further comprising:
a plurality of floating field plates formed on the FOX in the junction isolation region,
wherein no electrodes are connected to the plurality of floating field plates.

12. The semiconductor device of claim 9, further comprising:
a second P-TOP disposed on the first P-TOP formed in the DNW and spaced apart from the first P-TOP.
